(19) United States
(12) Patent Application Publication
(10) Pub. No.: US 2022/0123522 A1
(43) Pub. Date: Apr. 21, 2022

(54) PATTERN PROJECTOR BASED ON VERTICAL CAVITY SURFACE EMITTING LASER (VCSEL) ARRAY

(71) Applicant: Shenzhen Raysees Technology Co., Ltd., Shenzhen (CN)

(72) Inventors: Yang Wang, Dublin, CA (US); Danyong Li, Beijing (CN)

(73) Assignee: Shenzhen Raysees Technology Co., Ltd., Shenzhen (CN)

(21) Appl. No.: 17/428,000

(22) PCT Filed: Mar. 1, 2019
(86) PCT No.: PCT/CN2019/076666

§ 371 Date: Aug. 3, 2021

(51) Int. Cl. H01S 5/042; G02B 27/42; H01S 5/42

(52) U.S. Cl. CPC H01S 5/042; H01S 5/0234; H01S 5/423; G02B 27/4233

(57) ABSTRACT

The present invention discloses a pattern projector based on VCSEL array. The VCSEL array has a plurality of VCSELs configured in a regular pattern on a VCSEL chip. A certain number but not all of the VCSELs are selected for two groups. In one operational mode, VCSELs of one group are powered on to form a low-density irregular pattern. A lens system projects an image of the low-density irregular pattern on a diffractive optical element (DOE). The DOE multiplies a replica of the image and generates a matrix of the replicas on a target surface. In another operational mode, VCSELs of the two groups are powered on simultaneously or the second group is powered on alone to form a high-density irregular pattern. An image of the high-density irregular pattern is projected on the DOE. Thus, the pattern projector may provide irregular light patterns for low-resolution and high-resolution 3D sensing.

### TECHNICAL FIELD

This invention relates to pattern projector, and more specifically, to pattern projector based on Vertical Cavity Surface Emitting Laser (VCSEL) array.

### BACKGROUND ART

Three-dimensional (3D) sensing represents a future trend of smartphones. The 3D sensing technology is also expected to enhance the functions of robots, drones, and autonomous vehicles. Compared to conventional cameras which provide two-dimensional information, 3D sensing captures the depth data in addition to a flat image and thus enables accurate facial recognition, object recognition, gesture sensing, and environmental sensing. Moreover, it enhances augmented reality (AR) and virtual reality (VR) capabilities as well. 3D sensing includes the Time-of-Flight (TOF) method and the structured light method. In the TOF approach, the depth data is obtained by measuring the traveling time of light emitted from a light source, reflected from an object, and finally detected by a sensor. In the structured light approach, a predetermined pattern of dots is projected onto an object. The pattern is distorted after it is reflected by the 3D shape of the object. The depth data of the object is calculated by analyzing changes in the pattern. VCSEL arrays may be used as light sources for the TOF and the structured light methods. For instance, the TOF method may use a VCSEL array with a regular pattern where VCSELs are configured in a matrix format. The structured light method may use a patterned VCSEL array, where VCSELs form a predetermined irregular pattern of dots.

A VCSEL emits an output beam in the direction perpendicular to its top and bottom surfaces. To become a VCSEL array, a VCSEL chip may contain multiple VCSELs which generate multiple output beams. For instance, thousands of VCSELs may be formed on a chip. Thanks to the surface emitting feature, wafer-level processing and surface-mount techniques, which are well developed in the semiconductor industry, may be utilized to manufacture VCSEL array devices in high volume inexpensively. Because of a narrow spectrum and stability with respect to temperature, plus low cost and small size, VCSEL arrays are becoming the dominant light source in 3D sensing implementations.

In illumination applications, VCSEL emitters in a VCSEL array are arranged in a regular pattern. One often-used regular pattern is matrix, where the spacing between any two adjacent VCSEL emitters in a row or column is the same. For instance, a 30×30 VCSEL array has thirty emitters in each row and each column and the centers of any two adjacent emitters may be, for instance, a constant value of forty micrometers.

In structured light method of 3D sensing, however, the VCSEL emitters of a VCSEL array are arranged in a predetermined irregular pattern, which is determined by the specific algorithm used in the structured light method. Examples include random and pseudo-random patterns depending on the design.

A regular-patterned VCSEL array may be made by the same fabrication method as an irregular-patterned VCSEL array. Take a top-emitting VCSEL array for example. When a regular-patterned VCSEL array is made, VCSELs are formed on a substrate in a regular pattern. The VCSELs share a common cathode terminal and are separated from each other by isolation trenches. A contact is formed on top of each VCSEL. In the last fabrication step(s), a metal structure or metal layer is deposited above the VCSELs to connect all these top contacts. When an irregular-patterned VCSEL array is made, VCSELs are formed on a substrate in a predetermined irregular pattern. The VCSELs share a common cathode terminal and are separated by isolation trenches. Similarly, a contact is formed on top of each VCSEL. In the last fabrication step(s), a metal layer is deposited to connect all top contacts of the VCSELs. The main difference between making a regular-patterned VCSEL array and making an irregular-patterned VCSEL array is that they use different sets of masks. While the manufacturing process fully utilizes current fabrication techniques and processes, it is limited to only one design of patterned array, a regular pattern or an irregular pattern. Consequently, a regular-patterned VCSEL array and an irregular-patterned VCSEL array have to be designed and manufactured separately in order to meet different needs. A VCSEL array is either a regular-patterned array or an irregular-patterned array.

A VCSEL-array-based pattern projector comprises a VCSEL chip, a lens system, and a diffractive optical element (DOE). The VCSEL chip comprises a VCSEL array. When the VCSEL array is powered on, it emits laser beams configured in a pattern defined by the array, such as a regular pattern or irregular pattern. The lens system creates an image of the laser beams on the DOE. The DOE projects a multitude of replicas of the image onto a target surface. When the VCSEL array is regular patterned, a multitude of replicas of a regular pattern are projected. When the VCSEL array is irregular patterned, a multitude of replicas of an irregular pattern are projected. A pattern projector either comprises a regular-patterned VCSEL array for producing replicas of a regular pattern or comprises an irregular-patterned VCSEL array for producing replicas of an irregular pattern. Currently, most popular pattern projectors with VCSEL arrays are designed to project one single pattern of optical beams onto objects. Thus, for illumination applications and 3D sensing applications, two or more pattern projectors are required to produce multiple patterns.

### SUMMARY OF INVENTION

### Technical Problem

### Solution to Problem

### Technical Solution

The present invention discloses a pattern projector that is based on a VCSEL array. The VCSEL array comprises VCSELs configured in a regular pattern on a VCSEL chip. In one mode, where some VCSELs are powered on, the VCSEL array provides a low-density irregular pattern. In another mode, where more VCSELs are powered on, the VCSEL array provides a high-density irregular pattern. In yet another mode, where all VCSELs on the chip are powered on, the VCSEL array provides a regular pattern. The pattern projector makes use of the multi-mode VCSEL array to support low-resolution and high-resolution 3D sensing or render an illumination light source. The present invention significantly increases the versatility of the pattern projector and broaden its applicability to various fields. The two or more patterns, whether irregular or regular, can be activated alternatively or simultaneously according to various application scenarios. For instance, in a scenario where the requirement of the accuracy of depth calculation is not high, only the VCSELs forming the low-density irregular pattern are lit on. When the requirement of calculation accuracy is high, the VCSELs forming the high-density irregular pattern are lit on. This configuration can reduce the power consumption at the same time retain the accuracy for some usages.

In one embodiment, a pattern projector comprises a VCSEL chip, a lens system, and a DOE. The VCSEL chip comprises a VCSEL array that has multiple operational modes. In one mode, the VCSEL array generates low-density irregular-patterned laser beams. In another mode, the VCSEL array generates high-density irregular-patterned laser beams. In yet another mode, the VCSEL array generates regular-patterned laser beams. Consequently, the pattern projector has multiple operational modes. In one mode, the projector generates replicas of a low-density irregular pattern. In another mode, the projector generates replicas of a high-density irregular pattern. In yet another mode, the projector generates replicas of a regular pattern. Hence, one projector may produce low-density irregular patterns, high-density irregular patterns, or regular patterns, depending on the operational mode selected. The low-density irregular patterns, high-density irregular patterns, and regular patterns may be used for low-resolution 3D sensing, high-resolution 3D sensing, and illumination applications respectively.

In another embodiment, a pattern projector comprises a VCSEL chip which has a substrate and a plurality of VCSEL structures formed in a regular pattern on the substrate. The VCSEL structures share one electrode (e.g., the cathode terminal) and each have a contact serving as the other electrode (e.g., the anode terminal). A first customized metal layer is deposited above the plurality of VCSEL structures to electrically connect the contacts of a selected number but not all of the plurality of VCSEL structures. The selected VCSEL structures form an array of a predetermined first irregular pattern. A second customized metal layer, which is electrically insulated from the first metal layer, is deposited above the plurality of VCSEL structures to electrically connect the contacts of a selected number but not all of the remaining VCSEL structures. In one embodiment, the VCSEL structures connected by the first metal layer and the VCSEL structures connected by the second metal layer are interleaved on the substrate. In one operational mode, VCSEL structures of the predetermined first irregular pattern are powered on to generate low-density irregular-patterned laser beams. An image of the predetermined first irregular pattern is projected on a DOE by a lens system. Next, the DOE generates replicas of the image on a target surface. In another operational mode, VCSEL structures electrically connected to the first and second metal layers are powered on simultaneously to form a predetermined second irregular pattern with high density. High-density laser beams in the predetermined second irregular pattern are generated. An image of the predetermined second irregular pattern is projected on the DOE and replicas of the image are generated on the target surface. Alternatively, VCSEL structures electrically connected to the second metal layer may form an array of a predetermined third irregular pattern with high density. Consequently, in another mode, when VCSEL structures of the predetermined third irregular pattern are powered on, high-density laser beams in the predetermined third irregular pattern are generated.

Moreover, the second metal layer may be configured to connect all VCSEL structures which are not connected to the first metal layer. Hence, in yet another operational mode, all of the plurality of VCSEL structures is powered on to form the regular pattern via the first and second metal layers. In addition, as another alternative, the second metal layer may remain unchanged and still only connects part of the remaining VCSEL structures. Then a third customized metal layer may be deposited above the plurality of VCSEL structures to electrically connect the contacts of VCSEL structures which are not connected to the first and second metal layers. Thus in yet another operational mode, all of the plurality of VCSEL structures are powered on via the first, second, and third metal layers to form the regular pattern.

In yet another embodiment of the present invention, a pattern projector comprises a VCSEL chip that has a substrate, a plurality of VCSEL structures formed in a regular pattern on the substrate, and an optical component mounted above the plurality of VCSEL structures. The plurality of VCSEL structures shares one electrode (e.g., the cathode terminal) and each has a contact serving as the other electrode (e.g., the anode terminal). The optical component has a first and a second customized metal layer with contact pads formed on its bottom surface. The two metal layers are electrically insulated. The contact pads of the first metal layer are arranged in a mirror image of a predetermined first irregular pattern. The contact pads of the first and second metal layers together form a mirror image of the regular pattern. After the optical component is mounted above the plurality of VCSEL structures, each of the contact pads is electrically bonded with a corresponding contact of a VCSEL structure. Hence, a selected number but not all of the plurality of VCSEL structures are electrically connected by the contact pads of the first metal layer. The VCSEL structures which are connected to the contact pads of the first metal layer form an array of the predetermined first irregular pattern. In one operational mode, the VCSEL structures, which are connected to the contact pads of the first metal layer, are powered on to function as an irregular-patterned array. An image of the predetermined first irregular pattern is created on a DOE via a lens system. The DOE then generates replicas of the image on a target surface. In another operational mode, all of the VCSEL structures are powered on to function as a regular-patterned array. Via the lens system, an image of the regular pattern is projected on the DOE, which then generates replicas of the image on the target surface. Alternatively, the contact pads of the first and second metal layers together may form a mirror image of a predetermined second irregular pattern with high density. The VCSEL structures which are connected to the contact pads of the first and second metal layers form an array of the predetermined second irregular pattern with high density. Thus, two irregular patterns with different density values may be generated respectively. In addition, the contact pads of the second metal layer may form a mirror image of a predetermined third irregular pattern with high density. VCSEL structures which are connected to the contact pads of the second metal layer form an array of the predetermined third irregular pattern with high density. Consequently, in another mode, when VCSEL structures of the predetermined third irregular pattern are powered on, high-density laser beams in the predetermined third irregular pattern are generated.

In yet another embodiment, a pattern projector comprises a VCSEL chip which has a plurality of VCSEL structures mounted on a submount via the flip-chip method. The plurality of VCSEL structures are arranged in a regular pattern and share one electrode (e.g., the cathode terminal). Each VCSEL structure has a contact serving as the other electrode (e.g., the anode terminal). The submount has a first and a second customized metal layers with contact pads formed on its top surface. The contact pads of the first metal layer are arranged in an image of a predetermined first irregular pattern. The contact pads of the first and second metal layers together form an image of the regular pattern. After the plurality of VCSEL structures are mounted on the submount, each of the contact pads is electrically bonded with a corresponding contact of a VCSEL structure. Thus, a selected number but not all of the plurality of VCSEL structures are electrically connected by the contact pads of the first metal layer. The VCSEL structures which are connected to the contact pads of the first metal layer form an array of the predetermined first irregular pattern. In one operational mode, the VCSEL structures, which are connected to the contact pads of the first metal layer, are powered on to function as an irregular-patterned array. Resultantly, an image of the predetermined first irregular pattern is projected on a DOE by a lens system. Next replicas of the image are created on a target surface by the DOE. In another operational mode, all of the VCSEL structures are powered on to function as a regular-patterned array. An image of the regular pattern is projected on the DOE via the lens system. And then replicas of the image are created on a target surface by the DOE. Alternatively, the contact pads of the first and second metal layers together may form an image of a predetermined second irregular pattern with high density. The VCSEL structures which are connected to the contact pads of the first and second metal layers form an array of the predetermined second irregular pattern with high density. The predetermined second irregular pattern has higher density than the first irregular pattern. Thus, two irregular patterns with different density values may be generated. In addition, as an alternative, contact pads of the second metal layer may be arranged in an image of a predetermined third irregular pattern with high density. VCSEL structures which are connected to the contact pads of the second metal layer form an array of the predetermined third irregular pattern with high density. Consequently, in another mode, when VCSEL structures of the predetermined third irregular pattern are powered on, high-density laser beams in the predetermined third irregular pattern are generated.

In yet another embodiment of the present invention, the two or more customized metal layers discussed in the previous embodiments may be fabricated as separate parts or portions of a single metal layer electrically insulated by nonconductive material (e.g., Silicon Nitride).

### Advantageous Effects of Invention

### Advantageous Effects

The present invention has advantages over prior art pattern projectors because it has multiple operational modes to provide replicas of a low-density irregular pattern, a high-density irregular pattern, or a regular pattern. Therefore a pattern projector may serve as a source of the structured light for low-resolution and high-resolution 3D sensing applications or as a light source for illumination applications.

### BRIEF DESCRIPTION OF DRAWINGS

### Description of Drawings

The subject matter, which is regarded as the invention, is particularly pointed out and distinctly claimed in the claims at the conclusion of the specification. The foregoing and other features and also the advantages of the invention will be apparent from the following detailed description taken in conjunction with the accompanying drawings. Additionally, the leftmost digit of a reference number identifies the drawing in which the reference number first appears.

FIG. 1 illustrates a cross-sectional view of a prior art VCSEL array with a regular pattern;

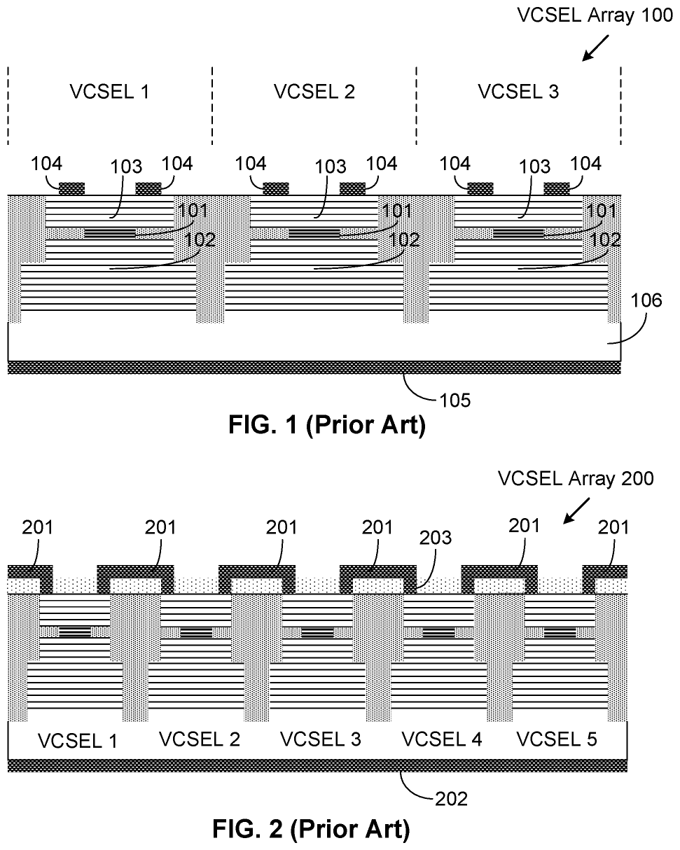

FIG. 2 illustrates a cross-sectional view of a prior art VCSEL array with a regular pattern;

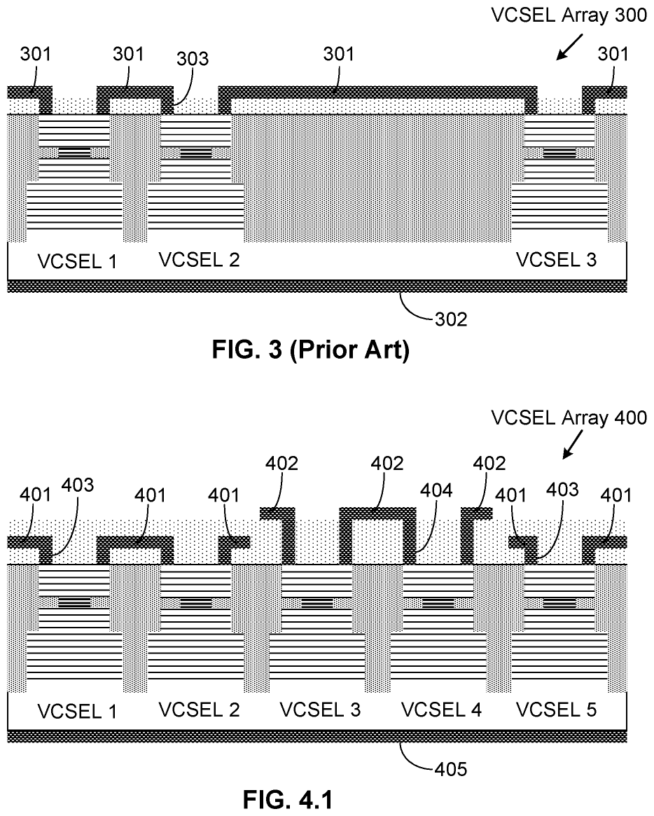

FIG. 3 illustrates a cross-sectional view of a prior art VCSEL array with a predetermined pattern;

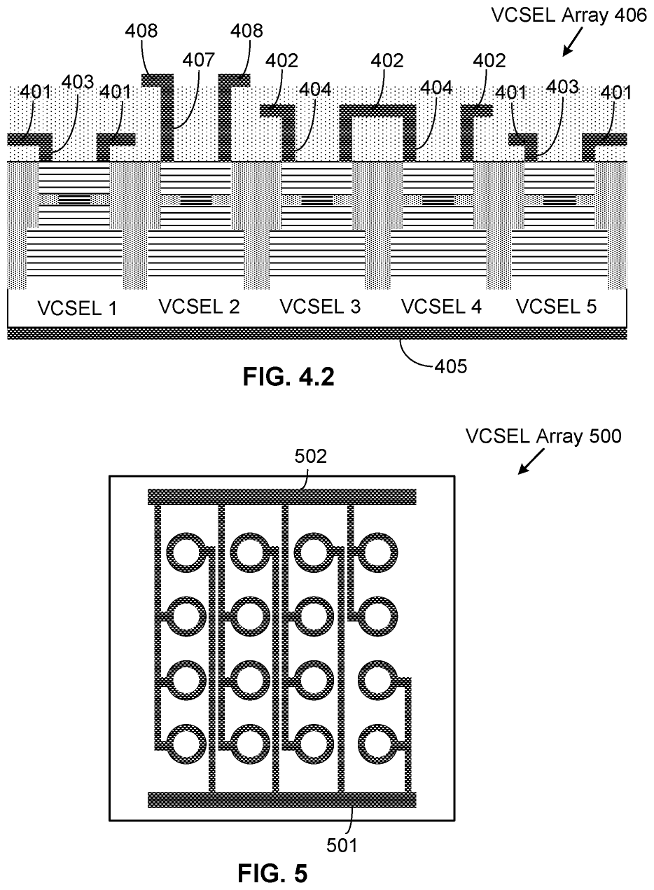

FIG. 4.1 illustrates a cross-sectional view of an exemplary VCSEL array, according to one embodiment of the present invention;

FIG. 4.2 illustrates a cross-sectional view of an exemplary VCSEL array, according to one embodiment of the present invention;

FIG. 5 illustrates an exemplary VCSEL array chip in a top view, according to one embodiment of the present invention;

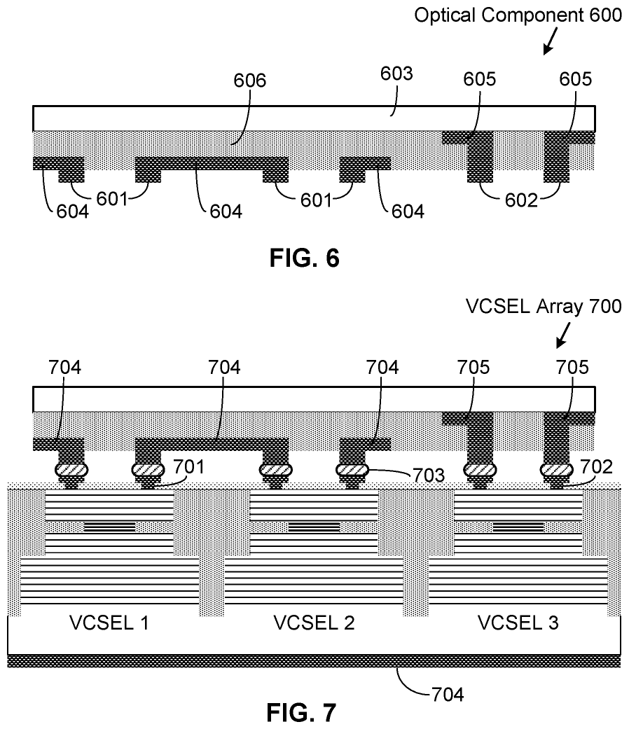

FIG. 6 illustrates a cross-sectional view of an exemplary optical component, according to two embodiments of the present invention;

FIG. 7 illustrates a cross-sectional view of an exemplary VCSEL array, according to one embodiment of the present invention;

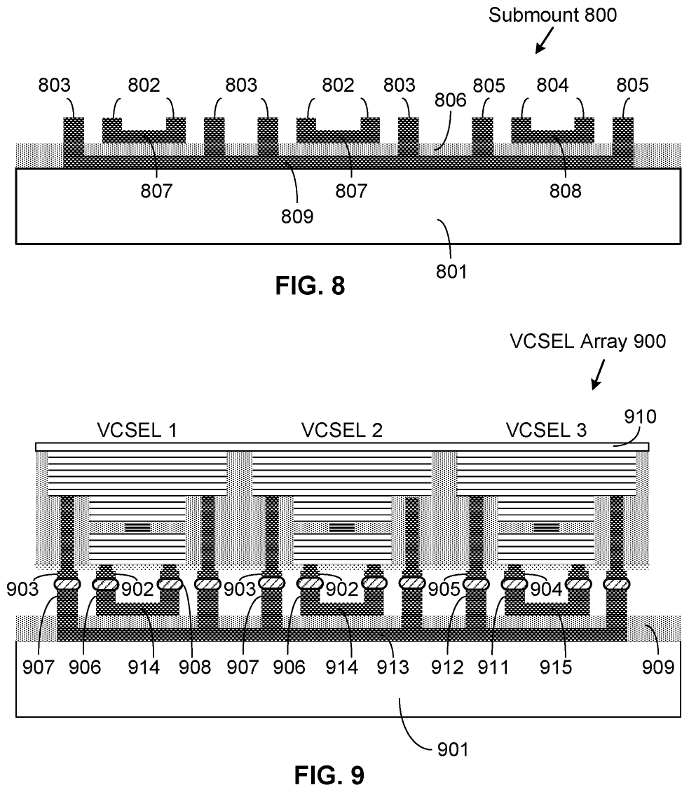

FIG. 8 illustrates a cross-sectional view of an exemplary submount, according to one embodiment of the present invention;

FIG. 9 illustrates a cross-sectional view of an exemplary VCSEL array, according to one embodiment of the present invention;

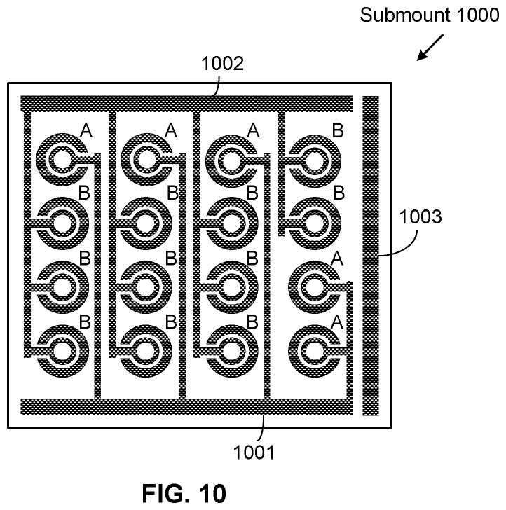

FIG. 10 illustrates an exemplary submount in a top view, according to the present invention;

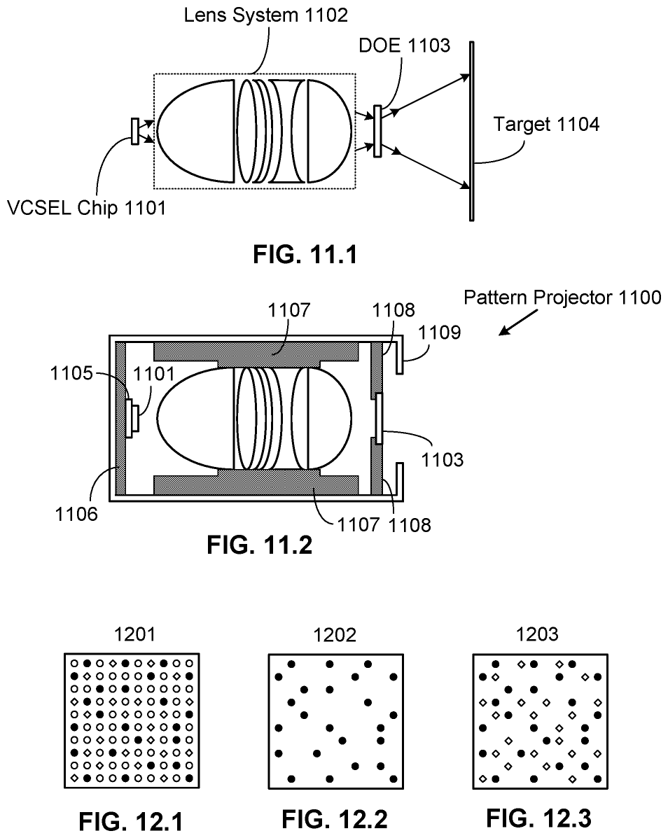

FIG. 11.1 illustrates an exemplary structure of a pattern projector in a cross-sectional view, according to one embodiment of the present invention;

FIG. 11.2 illustrates an exemplary structure of a pattern projector assembly in a cross-sectional view, according to one embodiment of the present invention;

FIGS. 12.1, 12.2, and 12.3 are three exemplary VCSEL patterns of a VCSEL chip in a top view, according to one embodiment of the present invention;

FIG. 13 illustrates graphically a result of pattern projection via a lens system;

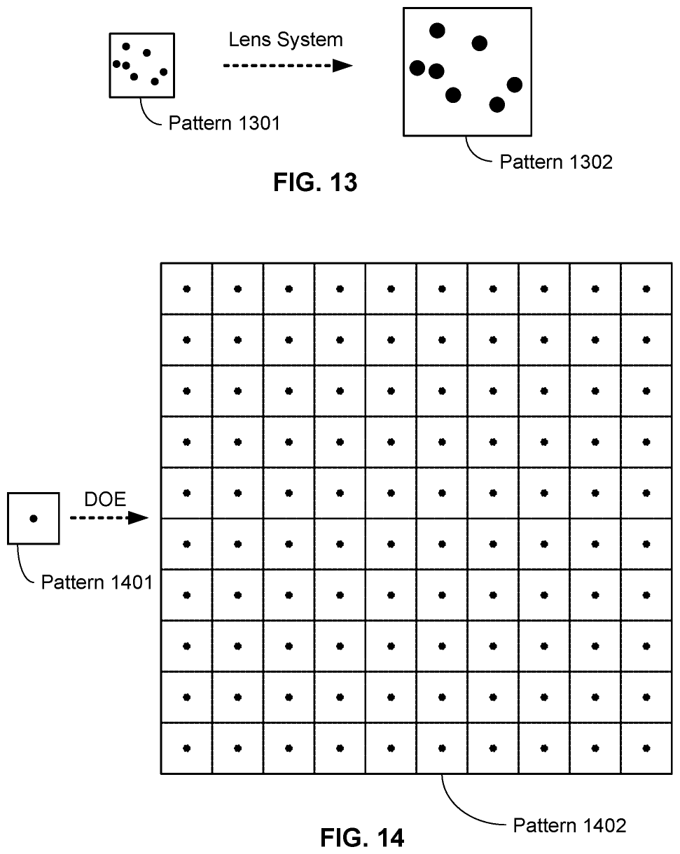

FIG. 14 illustrates graphically a result of pattern projection via a DOE;

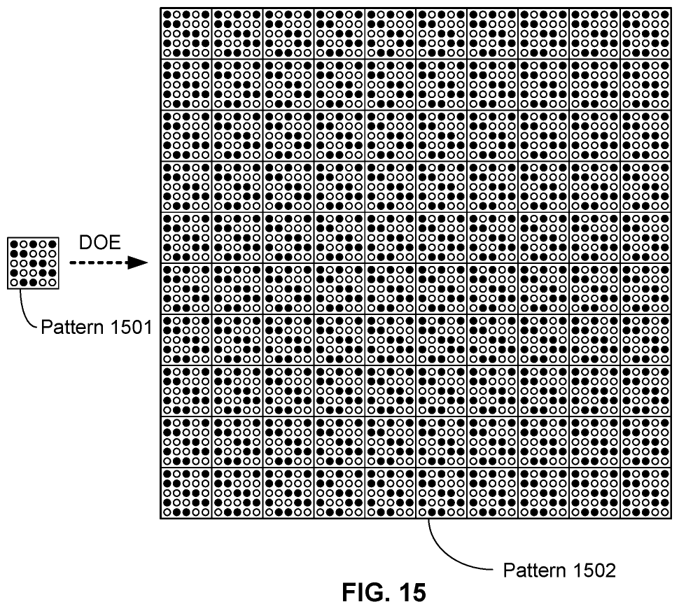

FIG. 15 illustrates graphically a result of pattern projection via a DOE, according to one embodiment of the present invention;

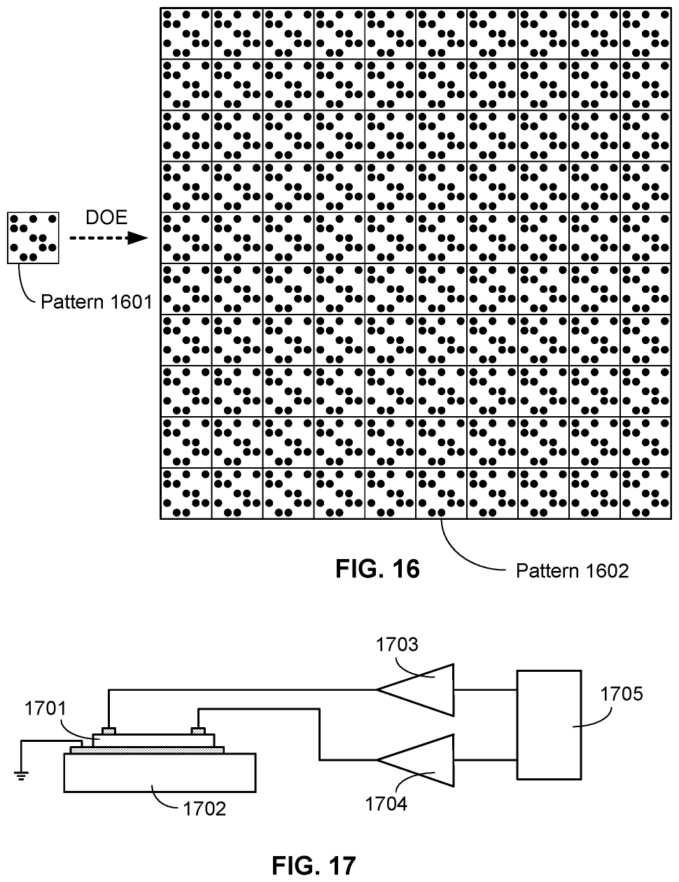

FIG. 16 illustrates graphically a result of pattern projection via a DOE, according to one embodiment of the present invention;

FIG. 17 illustrates an exemplary block diagram for VCSEL array control, according to one embodiment of the present invention.

### MODE FOR THE INVENTION

### Mode for Invention

FIG. 1 illustrates a prior art VCSEL array 100 in a cross-sectional view. Array 100 comprises VCSELs 1, 2, and 3 on a substrate 106. It should be noted that the array 100 may comprise thousands of VCSELs and only three VCSELs are shown here for simplification purposes. Similarly, in other figures and descriptions below, only a few VCSELs or part of an array are shown for simplification purposes. VCSEL 1, 2, or 3 represents a VCSEL structure or VCSEL emitter which emits a laser beam when charged with an electrical current. As used herein, a VCSEL, VCSEL structure, and VCSEL emitter have the same meaning and may be used interchangeably. As shown, each VCSEL includes an active region 101 and reflector regions 102 and 103. For a typical VCSEL, active region 101 may contain a multiple-quantum-well (MQW) structure, reflector region 102 may contain an n-type Distributed Bragg Reflector (DBR), and reflector region 103 may contain a p-type DBR. The quantum well region and DBRs are grown on substrate 106 in an epitaxial process. Substrate 106 has n-type doping. Reflector regions 102 and 103 and substrate 106 are electrically conductive. Metal contacts 104 are deposited on the p-type DBR regions. Metal layer 105 is deposited on the bottom surface of substrate 106. Metal contacts 104 and metal layer 105 serve as the anode and cathode terminals, respectively. It is noted that a metal layer may have various shapes and structures in two or three dimensions. Thus a metal layer may also be called a metal structure. “Metal layer” and “metal structure” have the same meaning and may be used exchangeably in discussions below. In addition, different metal structures or layers are electrically insulated.

As shown in FIG. 1, the plurality of VCSELs shares a common cathode but are separated by isolation trenches. When the array is in operation or electrically charged, each VCSEL emitter generates a laser beam. These VCSEL emitters are arranged in a regular pattern. For purpose of illustration, a VCSEL array of a regular or irregular pattern may also be called a regular-patterned or irregular-patterned VCSEL array.

A regular pattern, as used herein, may mean various configurations that follow certain rules. Examples of regular patterns include elements with equal spacing in one or more rows, elements with equal spacing in rows and columns, elements with equal spacing in concentric circles, etc. An irregular pattern, as used herein, may mean various configurations which don't follow any rule. Irregular patterns include random or pseudorandom patterns.

Prior art regular-patterned and irregular-patterned VCSEL arrays may be made with the same fabrication process, except using different lithographic masks. Both types of arrays have a common cathode terminal and connected anode terminals. All of the anode terminals are electrically connected by a metal layer in both cases. For instance as shown in FIG. 2, a prior art regular-patterned VCSEL array 200 contains five emitters from VCSEL 1 to VCSEL 5. A metal layer 202, serving as the common cathode, is deposited on the bottom substrate surface. An insulation layer (e.g. Silicon Nitride) is deposited on the top surfaces of p-type reflector regions. A plurality of vias 203 are etched on the insulation. A metal layer 201 is deposited to electrically connect all VCSELs through the vias. Array 200 represents a regular-patterned VCSEL array, where the emitters are configured in a regular pattern and all of the VCSEL are turned on when the array is in operation.

In FIG. 3, a prior art VCSEL array 300 is depicted. Array 300 contains VCSELs 1, 2, and 3, where the VCSELs are configured in a predetermined pattern. Like array 200 of FIG. 2, VCSELs 1, 2, and 3 have a common cathode 302. A metal layer 301 electrically connects the VCSELs through vias 303. When array 300 is turned on, a predetermined pattern of VCSEL emitters is formed. Thus, when a prior art method is used to make a VCSEL array, the array has a fixed pattern, either a regular pattern or an irregular pattern. After a VCSEL array is made, its pattern is fixed and can't be changed.

FIG. 4.1 illustrates an exemplary VCSEL array 400 in a cross-sectional view, according to one embodiment of the present invention. As shown, array 400 includes five VCSEL emitters from VCSEL 1 to VCSEL 5. A metal layer 405 is deposited on the bottom surface of the substrate and serves as the common cathode terminal for the VCSELs. Two metal layers 401 and 402 are deposited above the epitaxial regions, for example, in a sequential manner. Metal layer 401 is arranged to electrically connect VCSELs 1, 2, and 5 through vias 403. Metal layer 402 is configured to electrically connect VCSELs 3 and 4 through vias 404. The sections of layer 401 and 402 are respectively linked via connections not shown in the figure.

Metal layers 401 and 402 are electrically connected to different VCSELs and thus may create VCSEL arrays with different patterns. For instance, metal layer 401 may be deposited to connect a selected number but not all of the VCSELs. The selected VCSELs may form a predetermined first irregular pattern. On the other hand, metal layer 402 may be deposited to connect a selected number but not all of the remaining VCSELs which are not connected to metal layer 401. In one embodiment, the VCSELs connected by the metal layer 401 and the VCSELs connected by the metal layer 402 are interleaved in the VCSEL array 400. The VCSELs connected to metal layer 401 and 402 may form a predetermined second irregular pattern. As the second irregular pattern includes the first irregular pattern, it may the designed such that the first irregular pattern has relatively low density and the second irregular pattern has relatively high density. Thus, two irregular patterns may be generated by depositing two metal layers to connect selected but not all elements from a regular array. In certain cases, the two irregular patterns may be generated using different portions of one metal layer. Thus, when an electrical current is charged via metal layer 401, VCSEL array 400 may function as a low-density irregular-patterned array because only VCSELs of the first irregular pattern are lit up. When an electrical current is charged via both metal layers 401 and 402, VCSELs of the second irregular pattern are powered on. Then array 400 becomes a high-density irregular-patterned VCSEL array. The density of an irregular array is related to the resolution of 3D sensing. When the density becomes higher, more measurement points are configured on a target surface, which leads to higher measurement resolution. Since VCSEL array 400 may operate in low-density or high-density modes, a pattern projector based on the VCSEL array may have corresponding low-resolution and high-resolution modes for 3D sensing applications.

In addition, VCSEL structures electrically connected to metal layer 402 may form an array of a predetermined third irregular pattern with high density. Consequently, in another mode, when VCSEL structures of the predetermined third irregular pattern are powered on, high-density laser beams in the predetermined third irregular pattern are generated.

Alternatively, metal layer 402 may be configured to connect all the remaining VCSELs, instead of part of the remaining VCSELs which are not connected to layer 401. Thus, when an electrical current is charged via metal layer 401, VCSEL array 400 functions as an irregular-patterned array. When an electrical current is charged via both metal layers 401 and 402, all VCSELs are powered on. Consequently, array 400 becomes a regular-patterned VCSEL array. Hence, VCSEL array 400 may operate in two different modes, enabling an irregular pattern or a regular-pattern respectively. Optionally, another metal layer may be introduced for providing additional operational modes. For instance, a metal layer 408 may be deposited above metal layers 401 and 402, as shown exemplarily in FIG. 4.2. In the figure, a VCSEL array 406 is a modified array 400. Metal layer 408 is configured to electrically connect VCSEL 2 through vias 407. In one embodiment, metal layer 408 may be configured to connect all VCSELs which are not connected to metal layers 401 and 402. Therefore, when an electrical current is charged via metal layer 401, VCSEL array 406 may function as a low-density irregular-patterned array; when an electrical current is charged via both metal layers 401 and 402, array 406 becomes a high-density irregular-patterned VCSEL array; and when an electrical current is charged via metal layers 401, 402, and 408, all VCSELs are powered on and array 406 becomes a regular-patterned VCSEL array. Thus, VCSEL array 406 may provide a low-density irregular pattern, a high-density irregular pattern, and a regular pattern respectively. Resultantly, a pattern projector based on the VCSEL array may support low-resolution and high-resolution modes for 3D sensing plus proving a light source for illumination applications.

It is noted that as another alternative, metal layers 401, 402, and 408 may be fabricated as three electrically insulated portions of the same metal layer or two metal layers and achieve the same functions described above.

In discussions below, additional embodiments and methods are introduced to build a multi-mode VCSEL array which has a regular pattern. For simplicity reasons, examples are given which have the following arrangements: A selected number of VCSELs, which form a first irregular pattern on a chip, are connected to a first metal layer and the remaining VCSELs are connected to a second metal layer. The metal layers may be deposited on a VCSEL chip, a substrate, or a component of an array assembly. Thus the resultant VCSEL array has two modes, providing a first irregular pattern or a regular pattern respectively. However, VCSEL arrays discussed in the examples may be modified to have different or additional modes without mentioning. For instance, the second metal layer may connect not all but only part of the remaining VCSELs on a chip. Hence, VCSELs connected to the first metal layer may form a first irregular pattern with low-density. VCSELs connected to the first and second metal layers together may form a second irregular pattern with high-density. Moreover, VCSELs connected to the second metal layer may form a third irregular pattern with high-density. Thus the resultant VCSEL array may have multiple versions to provide a low-density irregular pattern and a high-density irregular pattern.

Furthermore, an additional metal layer may be deposited on the chip so that there are three metal layers. Accordingly, a selected number of VCSELs may be connected to a first metal layer, a selected number of the remaining VCSELs may be connected to a second metal layer, and the rest VCSELs may be connected to a third metal layer. VCSELs connected to the first metal layer form a low-density irregular pattern. VCSELs connected to the first and second metal layers together form a high-density irregular pattern. VCSELs connected to all three metal layers form the regular pattern. Therefore, instead of providing an irregular pattern and a regular pattern, VCSEL arrays discussed below may provide a low-density irregular pattern, a high-density irregular pattern, and optionally, a regular pattern.

FIG. 5 shows an exemplary VCSEL array 500 in a top view, according to one embodiment of the present invention. Note that this is not a cross-sectional view of the VCSEL Array 500 but a design view of the metals. The ring shaped objects represent metallic annular rings on the top surface of a VCSEL chip. The annular rings may be metal contacts or anode terminals of the VCSELs. Each annular ring encircles an output window of a VCSEL from where a laser beam is emitted. The short and long bars may represent two metal layers on the surface which electrically connects selected VCSELs respectively. Bond pads 501 and 502 are arranged for wire bonding. Bond wires may be bonded to connect the anode terminals of some VCSELs to a contact pad on a submount which carries the chip. Configuration of the annular rings illustrates a VCSEL array with a 4×4 matrix, i.e., an exemplary regular pattern. Bond pad 501 is connected to five VCSELs, which may be selected to form a predetermined pattern such as an irregular pattern. Thus, when an electrical current is charged via pad 501 and a common cathode terminal (not shown in the figure), VCSEL array 500 shows a predetermined pattern, such as a predetermined irregular pattern. When both pads 501 and 502 are used to charge an electrical current, all VCSELs are powered on. It becomes a VCSEL array of a regular pattern, a 4×4 matrix. Hence, the embodiment shown in FIG. 5 may be implemented to create a VCSEL array which has either a predetermined irregular pattern or a regular pattern. It should be noted that the above two metal layers may be fabricated as two insulated metal portions of the same metal layer and achieve the same functions described above.

Besides metal layers formed during the fabrication process of the VCSEL array, VCSELs of a regular-patterned array may also be selected to form a predetermined pattern by an external object, such as an optical component or a submount. FIG. 6 shows an exemplary optical component 600 in a cross-sectional view, which may be used to create a VCSEL array with either an irregular pattern or a regular pattern. Optical component 600 may be made using a base plate 603. Plate 603 may be made from a material which is transparent or substantially transparent at the wavelengths of interest. Its top and bottom surfaces may be coated with an antireflection layer to reduce reflection. Two metal layers 604 and 605 are deposited on plate 603 in a sequential manner using plating and lithographic processes. Alternatively, metal layers 604 and 605 may also be two portions formed from the same metal layer. The metal may be aluminum or copper. The sections of layer 604 and 605 are respectively connected (not shown in the figure) so that they are electrically two separate metal layers. Between the two metal layers is an insulation layer 606. Layer 606 may be arranged via a deposition process.

Like metal layers 401 and 402 of FIG. 4.1, layers 604 and 605 are used to create two patterns. They have contact pads 601 and 602 respectively. Contact pads 602 may be arranged to form a configuration which is a mirror image of a predetermined irregular pattern. After optical component 600 is mounted on a regular-patterned VCSEL array chip, contact pads 601 and 602 are connected to metal contacts of the VCSELs on the chip. The VCSELs, which are electrically connected to the contact pads 601, form the predetermined irregular pattern. In addition, all VCSELs on the chip may be electrically charged simultaneously via pads 601 and 602 to produce a regular pattern.

In FIG. 7, an exemplary VCSEL array 700 is illustrated in a cross-sectional view. It comprises a VCSEL array chip and an optical component attached to the chip. The chip contains a plurality of VCSELs, including VCSELs 1, 2, and 3, configured in a regular pattern. The VCSEL array chip may be fabricated by using the manufacturing process of a regular-patterned VCSEL array but without the metallization that completes the connection of the VCSELs. The optical component has two metal layers 704 and 705 deposited in a sequential manner on a downward facing surface. Alternatively, metal layers 704 and 705 may also be two portions of the same metal layer. Contact pads of the optical component which are connected to layer 704 are arranged in a mirror image of a predetermined pattern. As shown in the figure, VCSELs 1 and 2 have metal contacts 701. VCSEL 3 has metal contacts 702. Contact 701 and 702 are deposited on the p-type DBR reflector regions as the anode terminals of the VCSELs. The optical component is mounted on the VCSEL chip such that contact pads of the optical component are bonded with metal contacts 701 and 702 respectively. The contact pads are bonded on the chip by an electrically conductive adhesive material 703. Material 703 may be cured at an elevated temperature. As shown exemplarily, anode terminals of VCSELs 1 and 2 are electrically connected to metal layer 704, while the anode terminal of VCSEL 3 is connected to metal layer 705. The VCSELs have a common cathode terminal 704. Thus, when an electrical current is charged to VCSEL array 700 through metal layer 704, VCSELs 1 and 2, which are connected to the contact pads leading to metal layer 704, are powered on. VCSELs 1 and 2 form the predetermined pattern. Additionally, when both metal layers 704 and 705 are used to charge an electrical current, all VCSELs are powered on. Consequently, it becomes a regular-patterned VCSEL array. Therefore, an optical component may be used to make a VCSEL array have either a predetermined irregular pattern or a regular pattern. Because packaging processes are less complex than plating and lithographic processes, VCSEL array 700 may have advantages in cost and turnaround time over array 400.

Furthermore, an optical component may provide other functionalities in addition to presenting two patterns. For instance, optical structures may be created on the upward facing surface of an optical component. The structures may include lens-like objects generated by molding or etching processes. The lens-like objects may be aligned to each VCSEL and cause an output beam less or more divergent. Moreover, an optical system may be attached to an optical component to create a subassembly or an upgraded optical component. The optical system may contain certain optical elements or even complex lens systems. Thus an optical component may provide certain functionalities besides creating a predetermined irregular pattern and a regular pattern. As a subassembly may be manufactured in advanced or outsourced, it may increase production efficiency and cut cost and turnaround time.

FIG. 8 illustrates an exemplary submount 800 in a cross-sectional view, according to the present invention. In above discussions, VCSELs are of the top-emitting type, which means that laser beams are emitted through the p-type DBR region in a direction opposite to the substrate. In some cases, a back-side-emitting VCSEL is used. The VCSEL chip is turned upside down and packaged using flip-chip methods. For a backside-emitting VCSEL chip with flip-chip bonding, output laser beams go through the substrate and the chip's anode and cathode terminals face downward towards a submount. In such situations, a submount may be used to create a VCSEL array with an irregular pattern from a regular-patterned array. The submount may work in a similar way to an optical component as shown in the above examples.

Submount 800 has a base plate 801, where contact pads 802, 803, 804, and 805 are electrically connected respectively by metal layers 807, 808, and 809. For instance, pads 802 are electrically connected by metal layer 807, pads 804 by metal layer 808, and pads 803 and 805 by metal layer 809. Metal layers 807 and 808 are deposited on the top surface of the submount. Metal layer 809 is embedded in an insulation layer 806. Metal layers 807 and 808 may be two portions of the same metal layer or different metal layers. Metal layer 809 may be a portion of a metal layer which is electrically insulated from layers 807 and 808. The contact pads may be fabricated using plating, etching, and lithographic techniques. The configuration of contact pads 802 or 803, which are connected respectively, may represent an image of a predetermined pattern, such as an irregular pattern. The image may be used to create a VCSEL array with the predetermined pattern.

FIG. 9 illustrates an exemplary VCSEL array 900 in a cross-sectional view, according to the present invention. A VCSEL array die is flip-chip bonded on a submount. Before the die is mounted, its substrate portion is etched and an antireflection layer 910 is deposited to reduce reflection of an output laser beam. The die comprises VCSELs 1, 2, and 3 configured in a regular pattern. Metal contacts 902 and 903 are the anode and cathode terminals which are connected to the p-type DBRs and n-type DBRs of VCSELs 1 and 2 respectively. Metal contacts 904 and 905 are the anode and cathode terminals which are connected to the p-type DBR and n-type DBR of VCSEL 3 respectively. The submount has a base plate 901 and contact pads 906, 907, 911, and 912 deposited on the base plate. Contact pads 906 and 907 are arranged for VCSELs 1 and 2. Contact pads 911 and 912 are arranged for VCSEL 3. Metal contacts 902 and 903 of VCSELs 1 and 2 are bonded with contact pads 906 and 907 respectively by an electrically conductive adhesive material 908, while similarly metal contacts 904 and 905 of VCSEL 3 are bonded with contact pads 911 and 912 respectively.

Metal layers 914 and 915 may be two portions of the same metal layer or different metal layers. A metal layer 913 may be a portion of a metal layer which is electrically insulated from layers 914 and 915. Contact pads 906 which are aligned with metal contacts 902 are electrically connected by metal layer 914. Contact pads 911 which are aligned with metal contacts 904 are electrically connected by metal layer 915. Contact pads 907 and 912 which are aligned with metal contacts 903 and 905 respectively are electrically connected by metal layer 913. For instance, as shown in the figure, metal layers 914 and 915 may be deposited on the top surface of the submount, and metal layer 913 may be embedded in an insulation layer 909. Resultantly, the anode terminals of VCSELs 1 and 2 are electrically connected to metal layer 914, the anode terminal of VCSEL 3 is electrically connected to metal layer 915, and the cathode terminals of all VCSELs are connected to metal layer 913. Thus when the configuration of contact pads 906 or 907 represents an image of a predetermined pattern, VCSELs 1 and 2, which are connected to pads 906 and 907, form the predetermined pattern. When an electrical current is charged to the VCSELs through contact pads 906 and 907, only VCSELs 1 and 2 are turned on, which form a predetermined pattern defined by contact pads 906 or 907 on the submount. Resultantly, array 900 becomes a VCSEL array with a predetermined pattern, such as a predetermined irregular pattern.

VCSELs 1 and 2 are electrically insulated from VCSEL 3 and so are metal layers 914 and 915. Hence, when VCSELs 1 and 2 are turned on, VCSEL 3 is not affected electrically. However, when an electrical current is charged to the VCSELs though all contacting pads 906, 907, 911 and 912 on the submount, all VCSELs are turned on. Array 900 becomes a VCSEL array with the regular pattern. Therefore, like an optical component, a submount may be used to make a VCSEL array which may present either an irregular pattern or a regular pattern. Like the optical component method, the submount method has similar merits and advantages over prior art regular-patterned or irregular-patterned VCSEL arrays, such as improved cost and turnaround time.

FIG. 10 illustrates an exemplary submount 1000 in a top view, according to the present invention. The concentric rings may represent a pair of metallic contact pads deposited on the submount. The inner ring may represent a contact pad to be connected to an anode terminal of a VCSEL. The outer ring may represent a contact pad to be connected to a cathode terminal of a VCSEL. As aforementioned, the outer rings, to be connected to VCSELs' cathode terminals, may be electrically connected by a metal layer (not shown in the figure) beneath the surface, which may be embedded in an insulation layer on a base plate of the submount. The embedded metal layer has a contact area 1003 which may be used as a bonding pad for wire bonding. The submount makes VCSELs of a VCSEL die have a common cathode. Metal layers 1001 and 1002 may be two separate portions of a metal layer. The inner rings may be electrically connected to a corresponding metal layer respectively. In FIG. 10 for instance, inner rings marked by letter A are electrically connected to metal layer 1001 and inner rings marked by letter B are electrically connected to metal layer 1002.

Thus, after a VCSEL die with a 4×4 matrix configuration, i.e., a regular pattern, is flip-chip mounted on submount 1000, each pair of the inner and outer rings are connected to an anode and cathode terminal of a VCSEL. When an electrical current is charged to the VCSELs through metal layer 1001, only VCSELs corresponding to a pair of rings marked with letter A are turned on, which may form a predetermined pattern. Resultantly, a VCSEL array with the predetermined pattern is generated. When an electrical current is charged to the VCSELs through metal layers 1001 and 1002 together, all VCSELs are turned on, A VCSEL array with the 4×4 matrix configuration, a regular pattern, is generated. Therefore, a VCSEL array with a regular pattern may be switched between irregular-pattern mode and regular-pattern mode using a submount method.

In discussions above, regular-patterned VCSEL arrays are divided into two or three subarrays, a first subarray is formed by using a first metal layer (e.g., metal layer 401 in FIG. 4.1 and metal layer 604 in FIG. 6) to connect a selected number but not all of the VCSELs, and a second subarray is formed by using a second metal layer (e.g., metal layer 402 in FIG. 4.1 and metal layer 605 in FIG. 6) to connect the remaining VCSELs which are not connected to the first metal layer. And the first subarray could be in a predetermined irregular pattern. In another embodiment of the present invention, a first subarray is formed by using a first metal layer (e.g., metal layer 401 in FIGS. 4.2) to connect a selected number but not all of the VCSELs, and a second subarray is formed by using a second metal layer (e.g., metal layer 402 in FIG. 4.2) to connect a selected number of the remaining VCSELs which are not connected to the first metal layer. The first subarray is in a predetermined first irregular pattern. And combination of the first and second subarrays is in a predetermined second irregular pattern. In addition, a third metal layer may be deposited to connect all VCSELs not connected to the first and second metal layers. Thus, a VCSEL array may have multiple operational modes where the array is divided into two or three subarrays. The subarrays may be powered on individually or two or more of the subarrays may be powered on simultaneously. It is noted that more than three metal layers may be deposited on a VCSEL chip, which generates more subarrays in desired patterns and the resulting subarrays may be driven individually or some of the subarrays may be driven simultaneously to form a given pattern. As aforementioned, the metal layers may be deposited in a subsequent manner. Alternatively, the metal layers may be portions of a single metal layer, depending on the given circumstances and considerations.

When a VCSEL array generates low-density irregular-patterned, high-density irregular-patterned, or regular-patterned laser beams, a pattern projector based on the array may generate replicas of low-density irregular patterns, high-density irregular patterns, or regular patterns. FIG. 11.1 illustrates an exemplary structure of such a pattern projector, according to the present invention. The embodiment comprises a VCSEL chip 1101, a lens system 1102, and a DOE 1103. VCSEL chip 1101 comprises a VCSEL array, such as array 400, 500, 700, or 900 as discussed. Hence, chip 1101 may provide laser beams configured in a low-density irregular pattern, a high-density irregular pattern, and a regular pattern respectively. Lens system 1102 may comprise a group of lenses, as described exemplarily in the figure. Lens system 1102 may also contain a single lens. Lens system 1102 processes laser beams emitted from chip 1101 and projects an image onto a surface area of DOE 1103. The image projected on DOE 1103 corresponds to laser beams emitted from VCSEL chip 1101. The image is an enlarged or diminished replica of the VCSEL array pattern, or enlarged or diminished replica of the VCSEL array pattern which is inverted along a given axis.

Diffractive optical element or DOE is a generic term for various optical components that produce arbitrary distributions of light based on the principles of optical diffraction and optical interference. A DOE may use a thin micro-structured pattern to manipulate the phase of the light propagated through it. The pattern may be fabricated by photolithography and etching techniques which are well developed in the semiconductor industry. Through complete phase control, a DOE may process the light and convert it to almost any desired intensity profile. For applications in pattern projection, a DOE, such as DOE 1103, may be fabricated on an optically transparent substrate. For instance, DOE 1103 may be built on a fused silica substrate. DOE 1103 may be designed such that it functions as a beam splitter that splits an input beam into a multitude of beams that are spaced by specific angles. The splitting effect is caused by diffraction. A DOE makes an input beam diffracted after receiving it and causes the input beam to become a multitude of diffracted beams. The diffracted beams are projected on a target surface. When an image is generated on a surface area of DOE 1103 by lens system 1102, the DOE may multiply the image and produce a matrix of replicas of the image on a surface of a target 1104.

When VCSEL chip 1101 emits laser beams in a low-density pattern, the matrix contains low-density measurement points and the pattern projector works in a low-resolution mode. When chip 1101 emits laser beams in a high-density pattern, the matrix contains high-density measurement points and thus the pattern projector works in a high-resolution mode. Chip 1101 has relatively low power consumption when emitting laser beams in a low-density pattern and has relatively high power consumption when emitting laser beams in a high-density pattern, since fewer VCSELs are powered on in the former case. Thus, power consumption is reduced when a VCSEL array emits laser beams in a low-density pattern or low-density laser beams. In practice, it is desirable to generate high-density laser beams only when high-resolution is needed in measurements.

FIG. 11.2 shows a graphic illustration of a pattern projector assembly 1100 in a cross-sectional view, according to the present invention. Like what described in FIG. 11.1, projector 1100 has VCSEL chip 1101, a lens system like system 1102, and DOE 1103. Chip 1101 is mounted on a submount 1105 which is attached to a base plate 1106. Base plate 1106 is fixed on an interior surface of a housing 1109. Submount 1105 may have high thermal conductivity and function as a heat sink. For instance, it may be a synthetic-diamond submount or aluminum nitride (AlN) submount. Submount 1105 may also be a flexible printed circuits (FPC) board, which may comprise control circuits to drive VCSELs of chip 1101. Base plate 1106 may have high thermal conductivity too and may also work as a heat sink. The lens system has a holder 1007 which is attached to housing 1109. DOE 1103 is fixed on a holder plate 1108. Holder plate 1108 has a square-shaped or rectangle-shaped opening for mounting the DOE. A central part of DOE 1103 is configured to receive an image of a pattern that is projected by the lens system. The DOE then produces replicas of the image on a surface of a target.

FIG. 12.1 illustrates an exemplary VCSEL array 1201 in a top view, according to the present invention. Array 1201 has a regular pattern and comprises VCSELs which are represented by diamonds and circles in white and black color individually. VCSELs represented by the diamonds, white circles, and black circles form three preliminary patterns respectively. The three preliminary patterns or any two of the preliminary patterns are interleaved on a corresponding VCSEL chip. When the three preliminary patterns are combined, i.e., the diamonds, the white circles, and the black circles are combined, they form the regular pattern. If the black circles are selected or singled out, a VCSEL array 1202 is created, as illustrated graphically in FIG. 12.2. Assume that array 1202 has a first irregular pattern with low density, i.e., VCSELs represented by the black circles form the first irregular pattern with low density. In addition, when both the diamonds and the black circles are singled out, a VCSEL array 1203 is created, as illustrated graphically in FIG. 12.3. Assume that array 1203 has a second irregular pattern with high density, i.e., VCSELs represented by the diamonds and the black circles form the second irregular pattern with high density.

As discussed above, the VCSELs of array 1201 may share one electrode (e.g., the cathode terminal) and each may have a contact serving as the other electrode (e.g., the anode terminal). A first customized metal layer may be deposited above the VCSELs to electrically connect the contacts of VCSELs represented by the black circles. A second customized metal layer may be deposited above the VCSELs to electrically connect the contacts of VCSELs represented by the diamonds. Optionally, a third customized metal layer may be deposited above the VCSELs to electrically connect the contacts of VCSELs represented by the white circles. In the first operational mode, VCSELs represented by the black circles are powered on, i.e., array 1202 is powered on via the first metal layer. Resultantly, laser beams configured in the first irregular pattern, a low-density pattern, are produced for 3D sensing, such as low-resolution 3D sensing. In the second operational mode, VCSELs represented by the black circles and the diamonds are powered on, i.e., array 1203 is powered on via the first and second metal layers. Hence, laser beams configured in the second irregular pattern, a high-density pattern, are produced for 3D sensing, such as high-resolution 3D sensing. Optionally, in the third operational mode, all VCSELs of array 1201 are powered on via the three metal layers. Then, laser beams in the regular pattern are produced for illumination applications.

Alternatively, VCSELs represented by the diamonds or white circles may form a third irregular pattern with high density. The VCSELs may be powered on via the second or the third metal layer to generate high-density laser beams in the third irregular pattern. Thus a high-density irregular pattern may be generated via one metal layer as well.

After laser beams in an irregular pattern or regular pattern is created, the beams are processed by a lens system and an image may be projected onto a surface of a DOE. FIG. 13 shows the process graphically. A pattern 1301 represents an irregular pattern of a VCSEL array. When the VCSEL array is powered on, laser beams formed in the irregular pattern are generated. A lens system receives the laser beams and creates a light pattern 1302 on a surface of a DOE (not shown in the figure). Pattern 1302 may be an image of pattern 1302 without inversion or an image of pattern 1302 which is inverted around a given axis. The image may be enlarged or diminished compared to pattern 1301 depending on a system design. If pattern 1301 is irregular, the image shows an irregular pattern. If pattern 1301 is regular, the image presents a regular pattern.

When a light pattern is created on a DOE, the DOE multiplies it and produces a matrix of replicas of the pattern, as illustrated graphically in FIG. 14. In the figure, assume that a VCSEL chip has a single VCSEL and thus pattern 1401, which represents an image projected on a DOE, contains a single dot. Assume that the DOE is designed such that it splits the input beams, multiplies pattern 1401, and creates a pattern 1402 on a target surface. Pattern 1402 comprises a multitude of replicas of pattern 1401. The replica is not an exact copy of pattern 1401. Compared to pattern 1401, each replica may be enlarged or diminished in size. Moreover, a replica may be a deformed image of pattern 1401. For instance, if an image has a square shape, a replica of the image may not be a square. The replica may have an irregular shape, such as a pattern which represents a result after the four corners of a square are pulled outwards. Even though a replica may show a deformed image, an irregular pattern in the image may still remain irregular and may still be useful in 3D sensing applications. The replicas may form a 10×10 matrix, as shown in the figure. The replicas may also form other types of matrix, depending on a design of DOE.

Similarly, when a lens system projects a regular pattern 1501 onto a DOE, the DOE may multiply a replica of pattern 1501 and create a pattern 1502 on a target surface, as shown graphically in FIG. 15. Pattern 1502 comprises a matrix of replicas of pattern 1501. Compared to pattern 1501, each replica may be enlarged or diminished in size and some may be deformed. Pattern 1501 corresponds to a VCSEL array, where each black or white circle represents a VCSEL structure on a VCSEL chip exclusively. Regular pattern 1501 is created when VCSELs of all black and white circles are powered on. Assume that when only VCSELs which correspond to the black circles are powered on, an irregular pattern 1601 is created on the DOE surface, as illustrated graphically in FIG. 16. Consequently, the DOE may multiply a replica of irregular pattern 1601 and project a matrix of the replica as a pattern 1602 on a target surface.

Therefore, a pattern projector may utilize a VCSEL array that has multiple operational modes to create a matrix of either regular patterns or irregular patterns. In one operational mode, a selected number of the VCSELs form a low-density irregular array. The selected VCSELs generate laser beams in an irregular pattern with low density. In another operational mode, a selected number of the VCSELs form a high-density irregular array. The selected VCSELs generate laser beams in an irregular pattern with high density. In yet another operational mode, all VCSELs of the array may be powered on to generate laser beams in a regular pattern. The irregular or regular pattern may be processed by a lens system to create an image on a DOE. The DOE then generates a multitude of replicas of the image which corresponds to the irregular or regular pattern. So a VCSEL-array-based pattern projector may be used to produce replicas of either irregular patterns or regular patterns, e.g., a low-density irregular pattern, a high-density irregular pattern, or a regular pattern. Therefore, a pattern projector may support low-resolution and high-resolution measurements in 3D sensing applications or serve as an illumination source.

FIG. 17 is an exemplary schematic diagram which shows control of a VCSEL array in a pattern projector system. There are at least driver circuits 1703 and 1704 which supply electrical currents to VCSELs formed on a VCSEL chip 1701 respectively. The driver circuits are controlled by a controller 1705. Controller 1705 may include a data processing module, a communication module, and a memory module. The processing module may run programs stored at the memory module and send signals to driver circuits 1703 and 1704 to control electrical currents charged to the VCSELs. The communication module may communicate to other devices and pass signals to the processing module after receiving them. The processing module and communication module may be integrated on a single chip along with certain memory capacities. In addition, driver circuits 1703 and 1704 and controller 1705 may be integrated on a chip as well. Moreover, driver circuits 1703 and 1704 and controller 1705 may be integrated on chip 1701. Thus, the VCSELs and components may be built on a single chip.

VCSEL chip 1701 is mounted on a submount 1702. Chip 1701 comprises VCSELs in a regular-patterned array. As aforementioned, the VCSELs may share a cathode terminal and each may have a contact serving as the anode terminal. A number of the VCSEL may be selected to form a first group. VCSELs in the first group form a low-density irregular pattern. A number of the remaining VCSELs may be selected to form a second group on the chip. When VCSELs of the first and second groups are combined, they form a high-density irregular pattern. VCSELs of the first and second groups may be powered on simultaneously or separately. For instance, contacts of VCSELs of the first group may be electrically connected to driver circuit 1703. Contacts of VCSELs of the second group may be electrically connected to driver circuit 1704. In one operational mode, controller 1705 turns on driver circuit 1703, which in turn powers on VCSELs of the first group to form the low-density irregular pattern. Resultantly, laser beams in the low-density irregular pattern are produced. In another operational mode, controller 1705 turns on driver circuits 1703 and 1704 simultaneously. Then, VCSELs of the first and second groups are powered on and laser beams in the high-density irregular pattern are generated. In pattern projector cases as aforementioned, the laser beams, in the low-density irregular pattern or high-density irregular pattern, may be processed by a lens system and an image may be projected on a DOE. The DOE then generates a matrix of replicas of the image on a target surface. The replicas of the image may be used for low-resolution or high-resolution 3D sensing applications.

In addition, VCSELs of chip 1701 may form three or more groups and there may be three or more driver circuits configured to control VCSELs of the groups. Assume that the VCSELs are divided into three groups and VCSELs of each group are electrically connected to a corresponding metal layer. VCSELs of the first group may form a low-density irregular pattern; VCSELs of the second group may form a high-density irregular pattern; and VCSELs of all three groups together may form the regular pattern. For the three groups, three driver circuits may be arranged to supply power to them separately. And controller 1705 may be configured to control the three driver circuits respectively.

Although specific embodiments of the invention have been disclosed, those having ordinary skill in the art will understand that changes can be made to the specific embodiments without departing from the spirit and scope of the invention. The scope of the invention is not to be restricted, therefore, to the specific embodiments. Furthermore, it is intended that the appended claims cover any and all such applications, modifications, and embodiments within the scope of the present invention.

1. A pattern projector, comprising:
a plurality of Vertical Cavity Surface Emitting Laser (VCSEL) structures formed on a VCSEL chip, wherein the plurality of VCSEL structures is configured in a predetermined regular pattern;
a first metal structure electrically connecting a selected number but not all of the VCSEL structures;
a second metal structure electrically connecting at least some of the VCSEL structures which are not electrically connected to the first metal structure, wherein the first and second metal structures are electrically insulated from each other;
a lens system, wherein the lens system processes laser beams emitted from at least some of the VCSEL structures of the VCSEL chip; and
a diffractive optical element (DOE), wherein the DOE receives the laser beams processed by the lens system, generates diffracted beams, and projects the diffracted beams onto a surface of a target.

2. The pattern projector of claim 1 further comprising a first control circuit for driving the VSCEL structures electrically connected by the first metal structure and a second control circuit for driving the VCSEL structures electrically connected by the second metal structure.

3. The pattern projector of claim 2, wherein the VCSEL structures connected by the first metal structure form a first irregular pattern.

4. The pattern projector of claim 3, wherein the VCSEL structures connected by the second metal structure form a second irregular pattern.

5. The pattern projector of claim 3, wherein the VCSEL structures connected by the first metal structure and the VCSEL structures connected by the second metal structure form a second irregular pattern.

6. The pattern projector of claim 1, wherein VCSEL structures which are not electrically connected to the first metal structure or the second metal structure are electrically connected to a third metal structure, the first, second, and third metal structures are electrically insulated from each other.

7. The pattern projector of claim 6 further comprising a first control circuit for driving the VSCEL structures electrically connected by the first metal structure, a second control circuit for driving the VCSEL structures electrically connected by the second metal structure, and a third control circuit for driving the VCSEL structures electrically connected by the third metal structure.

8. The pattern projector of claim 1 further comprising an optical component, wherein the first and second metal structures are deposited on the optical component before the optical component is fixed above the VCSEL structures during a packaging process.

9. The pattern projector of claim 1 further comprising a submount, wherein the first and second metal structures are deposited on the submount before the VCSEL structures are mounted on the submount during a packaging process.

10. The pattern projector of claim 1, wherein the VCSEL structures connected by the first metal structure and the VCSEL structures connected by the second metal structure are interleaved.

11. A pattern projector, comprising:
a plurality of Vertical Cavity Surface Emitting Laser (VCSEL) structures formed on a VCSEL chip, wherein the plurality of VCSEL structures are configured in a predetermined regular pattern;
a first metal layer electrically connecting a selected number but not all of the VCSEL structures to form a first pattern, wherein the first pattern is an irregular pattern;
a second metal layer electrically connecting at least some of the VCSEL structures which are not electrically connected to the first metal layer to form a second pattern, wherein the first and second metal layers are electrically insulated from each other;
a lens system, wherein the lens system processes laser beams emitted from VCSEL structures of at least one of the first and second patterns; and
a diffractive optical element (DOE), wherein the processed laser beams received from the lens system are diffracted by the DOE.

12. The pattern projector of claim 11 further comprising a plurality of control circuits, wherein the plurality of control circuits drives VSCEL structures of the first and second patterns respectively.

13. The pattern projector of claim 12, wherein at least some of the VCSEL structures which are not in the first and second patterns are electrically connected to a third metal layer to form a third pattern, the first, second, and third metal layers are electrically insulated from each other.

14. The pattern projector of claim 12, wherein combination of the first and second patterns is an irregular pattern.

15. The pattern projector of claim 12, wherein the second pattern is irregular.

16. The pattern projector of claim 12, wherein the DOE generates a plurality of prearranged patterns on a surface of a target, and wherein the prearranged patterns correspond to at least one of the first and second patterns.

17. The pattern projector of claim 12 further comprising an optical component, wherein the first and second metal layers are deposited on the optical component before the optical component is fixed above the VCSEL structures during a packaging process.

18. The pattern projector of claim 12 further comprising a submount, wherein the first and second metal layers are deposited on the submount before the VCSEL structures are mounted on the submount during a packaging process.
